(19) United States
(12) Patent Application Publication
(10) Pub. No.: US 2006/0275965 A1
(43) Pub. Date: Dec. 7, 2006

(54) Plasma display device with improved heat dissipation efficiency

(76) Inventor: Kwang-Jin Jeong, Yongin-si (KR)

Correspondence Address: Robert E. Bushnell, Suite 300, 1522 K Street, N.W., Washington, DC, 20005-1202, US

(21) Appl. No.: 11/435,288

(22) Filed: May 17, 2006

(30) Foreign Application Priority Data
May 24, 2005 (KR) 10-2005-0043652

(51) Int. Cl. H01L 21/84; H01L 31/113

(52) U.S. Cl. 438/166; 257/291

(57) ABSTRACT

A plasma display device comprises: a plasma display panel for displaying an image; a chassis base mounted on a rear surface of the plasma display panel; a driving circuit unit mounted on a surface of the chassis base opposite to the plasma display panel; a signal transmitting device which electrically connects the driving circuit unit to the plasma display panel, and which has driving chips mounted on at least a portion thereof; and a protective plate which is fixed to the chassis base to protect the signal transmitting device, and which includes a plurality of heat sinks. The heat sinks uniformly cool driving chips mounted on at least one signal transmitting device. The heat dissipating efficiency of a heat sink located at a center of the protective plate is higher than that of a heat sink located at an edge of the protective plate.

### CLAIM OF PRIORITY

This application makes reference to, incorporates the same herein, and claims all benefits accruing under 35 U.S.C. §119 from an application for PLASMA DISPLAY DEVICE earlier filed in the Korean Intellectual Property Office on the 24^{th} of May 2005 and there, duly assigned Serial No. 10-2005-0043652.

### BACKGROUND OF THE INVENTION

1. Technical Field

The present invention relates to a plasma display device and, more particularly, to a plasma display device which includes heat sinks which can uniformly cool driving chips mounted on at least one signal transmitting device.

2. Related Art

A plasma display device is a flat display device using a plasma display panel (PDP) which is fabricated by forming electrodes on two substrates, attaching the two substrates to each other, injecting discharge gas therein, and sealing the two substrates.

The plasma display device is fabricated by forming the plasma display panel, connecting the plasma display panel to a chassis base on which elements for displaying an image (for example, driving circuits or the like) are mounted, and assembling a front case and a rear case.

Furthermore, since the plasma display device is thinner than a cathode ray tube (CRT) having a large area, it is suitable for providing a large screen within a small area which is light in weight. Also, unlike other flat display devices, such as a liquid crystal display (LCD), the plasma display device does not require an active element such as a transistor, and has beneficial characteristics such as wide viewing angle and a high degree of brightness.

Furthermore, in the plasma display panel, numerous pixels forming a screen are arranged in a matrix. In the plasma display panel, the pixels are driven by a method of applying a voltage to the electrodes without using an active element, that is, by a passive matrix method. The plasma display panel is classified into a direct current type and an alternating current type depending on the voltage signal for driving the electrodes. Also, the plasma display panel may be classified into a facing discharge type and a surface discharge type depending on the arrangement of two electrodes to which a discharge voltage is applied.

In the plasma display device using the aforementioned plasma display panel, discharge is generated in each pixel space of the plasma display panel to display an image. At this point, the discharge is generated in each pixel space by means of a voltage applied to the electrodes of the plasma display panel so as to generate plasma or excited atoms in each pixel space.

A portion of the power consumed in the discharge is emitted as light, but most of the power is converted into heat and consumed in the plasma display panel.

A material, such as a phosphor, of the plasma display panel is apt to be deteriorated or deformed due to a high temperature, and thus the life span of the plasma display panel is reduced.

Also, overheating of the plasma display panel, in particular, partial overheating, causes thermal expansion deformation and stress on a glass substrate, which is the base material of the plasma display panel, and thus the glass substrate may break.

Moreover, in the plasma display device, a large amount of power is consumed in the driving circuit connected to the electrodes of the plasma display panel. The power consumption generates heat. When the driving circuit is overheated, the circuit is apt to malfunction. That is, the discharge may be generated in a pixel space in which discharge must not be generated so that image quality deteriorates. Accordingly, in the plasma display device, how to efficiently emit the heat generated in the driving circuit is of importance. In particular, it is difficult to dissipate the heat generated in a portion in which a large amount of heat is generated, and cooling cannot be performed without using a heat sink, such as a tape carrier package (TCP)

Generally, in order to expel the heat generated in heat generating portions, such as the plasma display panel and the driving circuit, the plasma display device uses a chassis base attached to a rear surface of the panel. The chassis is formed by coupling a reinforcement member to a plate-shaped chassis base. At this point, the reinforcement member may be integrally formed on the chassis base. On a rear surface of the chassis base, a plurality of boards and a power supply device are mounted, circuits for driving the plasma display panel being formed and dispersed on the boards.

The chassis base supports the plasma display panel so as to reinforce the mechanical strength thereof. The chassis base also receives the heat from the plasma display panel or the driving circuit which contacts the chassis base and emits the heat to a space serving as a large heat dissipating area. Also, the chassis base uniformly disperses the partially concentrated heat. In order to perform the aforementioned functions, the chassis base is formed of metal, such as aluminum, having a superior thermal conductivity.

However, in a tape carrier package (TCP) or a chip on film (COF) which connects signal electrodes, which are connected to the pixels of the plasma display panel, to the driving circuit for driving the electrodes, and which has driving chips, it is especially difficult to cool the driving chips.

More particularly, the driving chips of the TCP or the COF are not mounted on a separate circuit board, in contrast to other driving circuits. That is, when a separate fixing structure does not exist, the driving chips are located at the middle of a signal line for connecting the driving circuit and the electrodes of the panel so that the driving chips are located, together with the signal line, at an empty space. However, the driving chips of the TCP or the COF generate a large amount of heat, and direct heat dissipation to the air is not efficient. Accordingly, the driving chips are mounted in such a manner that the driving chips contact a bent end of the chassis base or a protective plate so as to emit heat.

In particular, in the case where the driving chips contact the protective plate, the protective plate includes heat dissipating plates, such as heat sinks, to increase heat dissipating efficiency.

However, since the heights of the heat sinks are uniform, the temperature of the driving chip located at a center of the protective plate is higher than that of the driving chip located at an edge of the protective plate. This is because it is more difficult for the driving chip located at the center of the protective plate to contact fresh air than it is for the driving chip located at the edge of the protective plate to contact fresh air.

In addition, since the heat generated at the driving chip located at the center of the protective plate is added to the heat generated at other elements near the center, the temperature of the driving chip located at the center of the protective plate is higher than that of the driving chip located at the edge of the protective plate

### SUMMARY OF THE INVENTION

The present invention has been developed in order to solve the aforementioned problems, and an object of the present is to provide a plasma display device which includes heat sinks for uniformly cooling driving chips mounted on at least one signal transmitting device.

According to the present invention, heat sinks are attached to a protective plate so as to cool driving chips mounted on at least one signal transmitting device for connecting a plasma display panel to a driving circuit unit, and the heat dissipating efficiency of the heat sink located at a center of the protective plate is higher than that of the heat sink located at an edge of the protective plate. Thus, cooling irregularities can be solved in accordance with the location of the driving chip.

According to another aspect of the present invention, a plasma display device comprises: a plasma display panel for displaying an image; a chassis base mounted on a rear surface of the plasma display panel; a driving circuit unit mounted on a surface of the chassis base opposite to the plasma display panel; a signal transmitting device which electrically connects the driving circuit unit to the plasma display panel, and which has driving chips mounted on at least a portion thereof; and a protective plate which is fixed to the chassis base to protect the signal transmitting device, and which includes a plurality of heat sinks. The heat dissipating efficiency of the heat sink located at a center of the protective plate is higher than that of the heat sink located at an edge of the protective plate.

At this point, high heat dissipating efficiency means that heat is transferred to a greater degree from a heating source to air at low temperature at a location of the heat sink.

The heat dissipating area of the heat sink located at the center of the protective plate is greater than that of the heat sink located at the edge of the protective plate.

For example, the length of the heat sink located at the center of the protective plate may be greater than that of the heat sink located at the edge of the protective plate. Alternatively, the height of the heat sink located at the center of the protective plate may be greater than that of the heat sink located at the edge of the protective plate.

The chassis base further includes a reinforcement member corresponding to the protective plate, and the protective plate may be coupled to the reinforcement member through a screw fixed to the chassis base.

A first thermal conductive medium interposed between the driving chips and the reinforcement member, and a second thermal conductive medium interposed between the driving chips and the protective plate, may be further included in the invention.

The first thermal conductive medium and the second thermal conductive medium may be made of any one of a material obtained by adding a thermal conductive filler to a solid metal foil, an acrylic material, graphite, or silicon. Alternatively, the first thermal conductive medium and the second thermal conductive medium may be made of any one of a gelled silicon sheet having a standard thermal conductivity and a rubber sheet.

The heat sinks may be made of aluminum.

The signal transmitting device on which the driving chips are mounted may be any one of a tape carrier package (TCP) or a chip on film (COF).

A heat dissipating sheet mounted on the rear surface of the plasma display panel may be further included.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an exploded perspective view of a plasma display panel according to an embodiment of the present invention;

FIG. 2A is a partial cross-section view of a peripheral portion in which driving chips of a signal transmitting device are mounted in the plasma display device according to a first embodiment of the present invention;

FIG. 2B is a perspective view of the protective plate, including heat sinks, in the plasma display device according to the first embodiment of the present invention;

FIG. 2C is a front view of the protective plate on which the heat sinks shown in FIG. 2B are mounted;

FIG. 3A is a partial cross-section view of a peripheral portion in which driving chips of a signal transmitting device are mounted in the plasma display device according to a second embodiment of the present invention;

FIG. 3B is a perspective view of the protective plate, including heat sinks, in the plasma display device according to the second embodiment of the present invention; and

FIG. 3C is a plan view of the protective plate on which the heat sinks shown in FIG. 3B are mounted.

### DETAILED DESCRIPTION OF THE INVENTION

Hereinafter, an exemplary embodiment of the present invention will be described in detail with reference to the accompanying drawings, in which like reference numerals denote like elements.

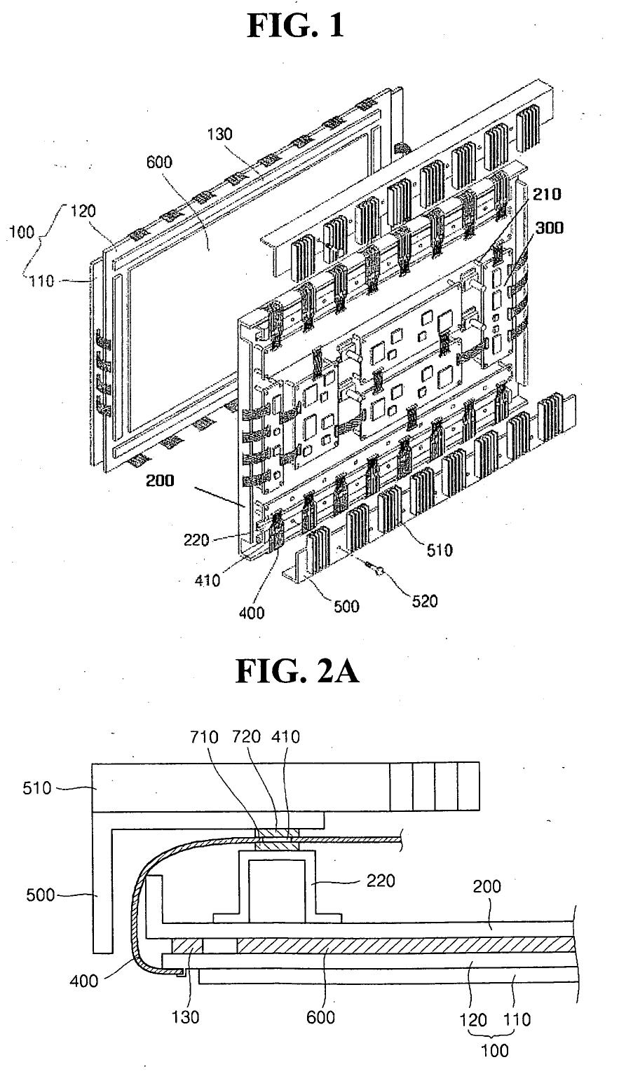

FIG. 1 is an exploded perspective view of a plasma display panel according to a first embodiment of the present invention.

Referring to FIG. 1, the plasma display device according to the present embodiment includes a plasma display panel 100 for displaying an image, a chassis base 200 disposed on a rear surface of the plasma display panel 100, a driving circuit unit 300 disposed on a surface of the chassis base 200 opposite to the plasma display panel 100, at least one signal transmitting device 400 which electrically connects the driving circuit unit 300 to the plasma display panel 100, and which has driving chips mounted on at least a portion thereof, and a protective plate 500 which is fixed to the chassis base 200 to protect the signal transmitting device 400, and which includes a plurality of heat sinks 510.

The plasma display panel 100 includes a front substrate 110 and a rear substrate 120, and enables a phosphor to emit light using ultraviolet rays generated by plasma discharge of gas filled therein, thereby displaying an image.

More particularly, the plasma display panel 100 includes a discharge cell (not shown) which is formed between the front substrate 110 and the rear substrate 120, and in which discharge is generated, discharge gas which is deposited in the discharge cell to generate a plasma discharge, a phosphor coated on a surface of the discharge cell, and electrodes (not shown) to which a voltage is applied. The plasma discharge is generated in the discharge cell by direct current voltage or alternating current voltage applied to the electrodes, and ultraviolet rays generated by the plasma discharge excites the phosphor to emit visible rays, thereby display the image.

Furthermore, an adhesive sheet 130 is attached to the rear surface of the plasma display panel 100 for attaching the plasma display panel 100 to the chassis base 200.

Accordingly, the chassis base 200 is attached to the rear surface of the plasma display panel 100 by means of the adhesive sheet 130. The adhesive sheet 130 is made of an adhesive material, such as a double sided tape. Also, the chassis base 200 includes a plurality of pressing holes (not shown) in which a plurality of bosses 210 for fixing the driving circuit unit 300 to the chassis base 200 is pressed. In addition, the chassis base 200 includes a reinforcement member 220, which is coupled to a portion of the chassis base 200 by means of the protective plate 500 and a screw 520 so as to prevent bending or deformation of the chassis base 200.

The chassis base 200 supports the plasma display panel 100 by means of the adhesive sheet 130 and supports the driving circuit unit 300 by means of the bosses 210.

The driving circuit unit 300 is mounted on a surface of the chassis base 200 opposite to the plasma display panel 100 by means of the bosses 210. Also, the driving circuit unit 300 includes electrode switching elements for controlling electrodes (not shown) which are included in the plasma display panel 200 and electrical signals applied to the electrodes.

Furthermore, a plurality of boss coupling holes (not shown) coupled to the bosses 210 are formed in the driving circuit unit 300.

The signal transmitting device 400 electrically connects the plasma display panel 100 to the driving circuit unit 300 so as to transmit the electrical signals of the driving circuit unit 300 to the plasma display panel 100. The signal transmitting device 400 includes driving chips 410 which are attached to a portion thereof. The driving chips 410 are thermally connected to the protective plate 500 and the reinforcement member 220 of the chassis base 200 by means of a thermal conductive medium (not shown).

The signal transmitting means 400, on which the driving chips 410 are mounted, receives the electrical signals from the driving circuit unit 300, generates driving signals at the driving chips 410 in response to the electrical signals, and transmits the driving signals to the electrodes of the plasma display panel 100. That is, the signal transmitting means 400 converts the electrical signals of the driving circuit unit 300 into the driving signals, and transmits the driving signals to the plasma display panel 100 so as to drive the plasma display panel 100.

In addition, the signal transmitting means 400 may be a tape carrier package (TCP) or a chip on film (COF).

The protective plate 500 is fixed to the reinforcement member 220 of the chassis base 200 by the screw 520 so as to protect the signal transmitting means 400.

Furthermore, the heat sinks 510 for dissipating the heat generated at the driving chips 410 are attached to portions of the protective plate 500 which are thermally connected to the driving chips 410 of the signal transmitting means 400. The heat sink 510 may be composed of a heat dissipating plate which is made of a superior thermal conductive material, such as aluminum.

The heat dissipating efficiency of a heat sink 510 located at the center of the protective plate 500 is higher than that of a heat sink 510 located at the edge of the protective plate 500.

This is because it is more difficult for the signal transmitting means 400 located at the center of the protective plate 500 to contact fresh air than it is for the signal transmitting means 400 located at the edge of the protective plate to contact fresh air. In addition, this is because the heat generated at the signal transmitting means 400 located at the center of the protective plate 500 is added to the heat generated at the other elements near the center, and thus the temperature of the signal transmitting means 400 located at the center of the protective plate 500 is higher than that of the signal transmitting means 400 located at the edge of the protective plate 500.

Furthermore, a heat dissipating sheet 600 for dissipating the heat of the plasma display panel 100 is preferably included between the plasma display panel 100 and the chassis base 200. The heat dissipating sheet 600 is made of a superior thermal conductive material.

The heat dissipating sheet 600 dissipates the heat generated at the plasma display panel 100 so as to prevent the temperature of the plasma display panel 100 from increasing to more than a predetermined temperature, and so as to prevent the plasma display panel 100 from being deformed by the heat or damaged by external impact.

The heat dissipating method using the heat dissipating sheet 600 may vary according to the shape of the chassis base 200.

When the chassis base 200 is made of a predetermined metal material, the heat dissipating sheet 600 may transfer the heat of the plasma display panel 100 to the chassis base 200 by contact with the chassis base 200.

Moreover, when the chassis base 200 is made of a predetermined plastic material, the heat dissipating sheet 600 may directly emit the heat of the plasma display panel 100 to the air without contacting the chassis base 200.

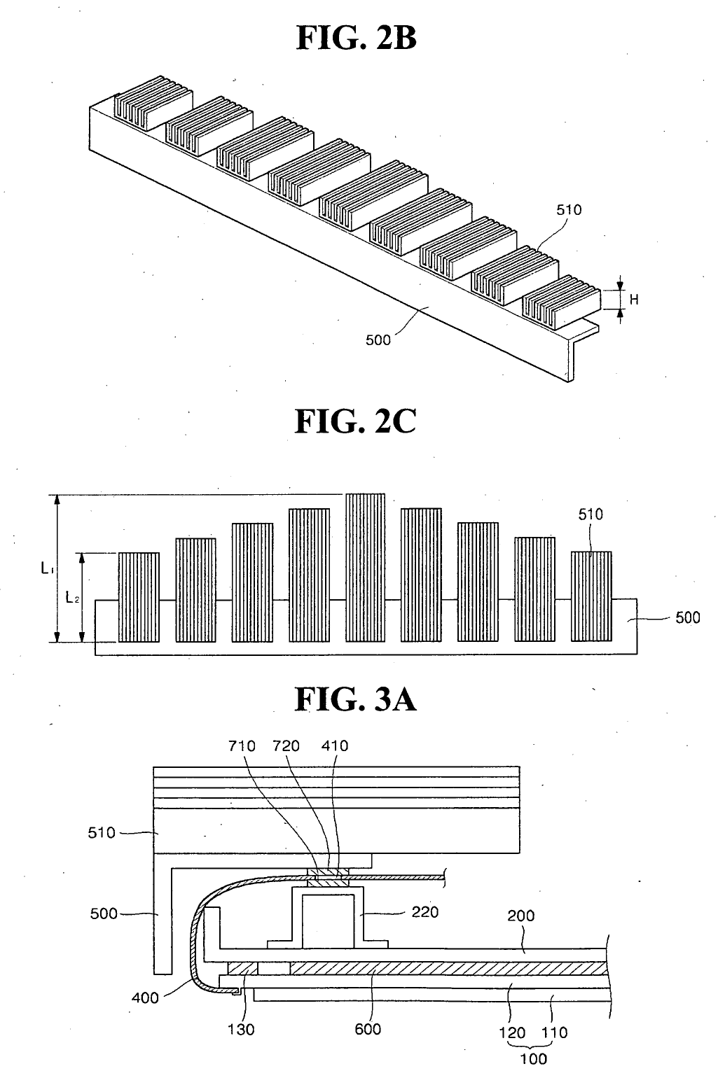

FIG. 2A is a partial cross-section view of a peripheral portion in which the driving chips of the signal transmitting means are mounted in the plasma display device according to a first embodiment of the present invention, FIG. 2B is a perspective view of the protective plate including the heat sinks in the plasma display device according to the first embodiment of the present invention, and FIG. 2C is a front view of the protective plate on which the heat sinks shown in FIG. 2B are mounted. In this regard, the plasma display panel 100, the chassis base 200 and the protective plate 500 of FIG. 1 are assembled in the plasma display device.

Referring to FIGS. 2A thru 2C, the chassis base 200 having the reinforcement member 220 is coupled to the plasma display panel 100 by the adhesive sheet 130. At this point, the heat dissipating sheet 600 for dissipating the heat of the plasma display panel 100 is interposed between the chassis base 200 and the plasma display panel 100.

The electrodes of the plasma display panel 100 are electrically connected to the driving circuit unit 300 through the signal transmitting means 400. At this point, the driving chips 410 of the signal transmitting means 400 are disposed on the reinforcement member 220, and a first thermal conductive medium 710 is interposed between the driving chips 410 and the reinforcement member 220.

When the first thermal conductive medium 710 is a solid thermal conductive medium, the first thermal conductive medium 710 may include a material obtained by adding a thermal conductive filler to a metal foil having high malleability or high ductility, or to an acrylic material, graphite, silicon, or equivalents thereof. However, the present invention is not limited to this. Also, when the first thermal conductive medium 710 is a fluidic thermal conductive medium, the first thermal conductive medium 710 may includes a gelled silicon sheet having a standard thermal conductivity, a rubber sheet, or equivalents thereof. However, the present invention is not limited to this.

The protective plate 500 is coupled to the reinforcement member 220 through screws (not shown) which are fixed to the chassis base 200. At this point, a second thermal conductive medium 720 is interposed between the protective plate 500 and the driving chips 410. The second thermal conductive medium 720 may be made of the same material as the first thermal conductive medium 710, but the present invention is not limited to this.

Also, the heat sinks 510 are mounted on the surface of the protective plate 500 opposite to the reinforcement member 220 so as to correspond to the driving chips 410, respectively.

At this point, the heat dissipating efficiency of the heat sink 510 located at the center of the protective plate 500 may be higher than that of the heat sink 510 located at the edge of the protective plate 500.

For example, the heat dissipating area of the heat sink 510 located at the center of the protective plate 500 may be higher than that of the heat sink 510 located at the edge of the protective plate 500.

In particular, when the heights of the heat sinks 520 are uniform, a length L1 of the heat sink 510 located at the center of the protective plate 500 may be greater than a length L2 of the heat sink 510 located at the edge of the protective plate 500.

Thus, the heat generated at the center of the protective plate 500 can be more efficiently dissipated.

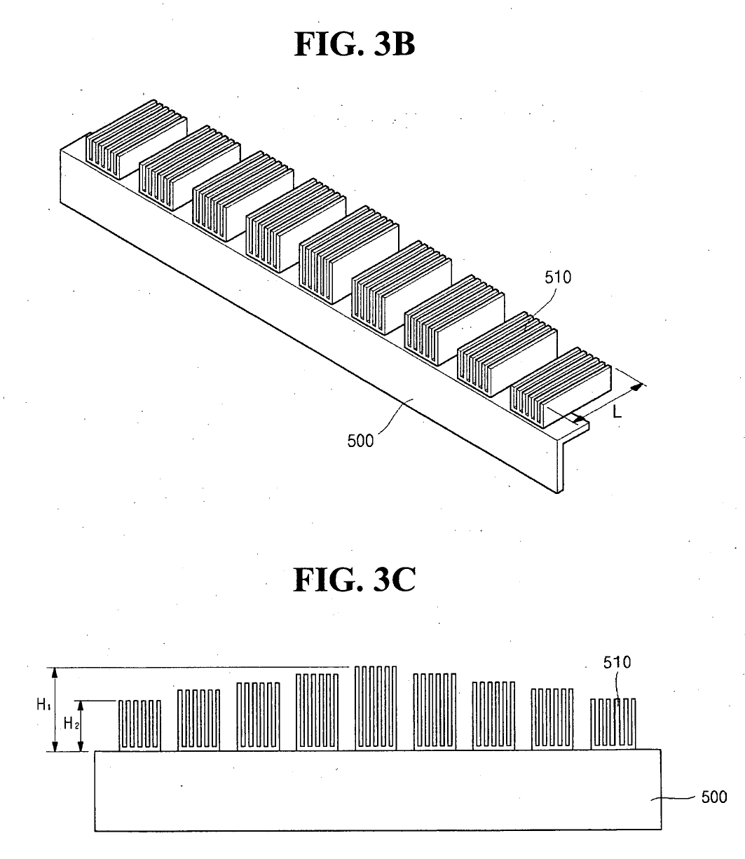

FIG. 3A is a partial cross-section view of a peripheral portion in which the driving chips of the signal transmitting means are mounted in the plasma display device according to a second embodiment of the present invention, FIG. 3B is a perspective view of the protective plate including heat sinks in the plasma display device according to the second embodiment of the present invention, and FIG. 3C is a plan view of the protective plate on which the heat sinks shown in FIG. 3B are mounted. In this regard, the plasma display panel 100, the chassis base 200 and the protective plate 500 of FIG. 1 are assembled in the plasma display device.

Referring to FIGS. 3A thru 3C, the plasma display device according to the second embodiment is generally similar in structure to the plasma display device shown in FIG. 1 and FIGS. 2A thru 2C.

However, the plasma display device according to the second embodiment is different from the plasma display device shown in FIG. 1 and FIGS. 2A thru 2C in that, in the second embodiment, lengths L of the heat sinks 510 mounted on the protective plate 500 (see FIG. 3B) are uniform and a height H1 of the heat sink 510 located at the center of the protective plate 500 is greater than a height H2 of the heat sink 510 located at the edge of the protective plate 500 (see FIG. 3C).

More particularly, the protective plate 500 is coupled to the reinforcement member 220 by screws (not shown) fixed to the chassis base 200, and the heat sinks 510 having a uniform length L are mounted on a surface of the protective plate 500 opposite to the reinforcement member 220 so as to correspond to the driving chips 410, respectively.

At this point, the height H1 of the heat sink 510 located at the center of the protective plate 500 is greater than the height H2 of the heat sink 510 located at the edge of the protective plate 500 so that the heat dissipation efficiency of the heat sink 510 located at the center of the protective plate 500 is greater than that of the heat sink 510 located at the edge of the protective plate 500.

As described above, in the plasma display device according to the present invention, since the heat dissipating area of the heat sink 510 located at the center of the protective plate 500 is greater than that of the heat sink 510 located at the edge of the protective plate 500, the driving chips 410 of the signal transmitting means 400 are uniformly cooled.

According to the present invention, it is possible to provide a plasma display device which includes heat sinks which uniformly cool driving chips mounted on at least one signal transmitting means.

While the present invention has been particularly shown and described with reference to exemplary embodiments thereof, it will be understood by those skilled in the art that various changes in form and detail may be made therein without departing from the spirit and scope of the invention as defined by the appended claims. Therefore, the scope of the invention is defined by the appended claims, and all differences within the scope will be construed as being included in the present invention.

1. A plasma display device, comprising:
a plasma display panel for displaying an image;
a chassis base mounted on a rear surface of the plasma display panel;
a driving circuit unit mounted on a surface of the chassis base opposite to the plasma display panel;
a signal transmitting device which electrically connects the driving circuit unit to the plasma display panel, and which has driving chips mounted on at least a portion thereof;
a protective plate which is fixed to the chassis base to protect the signal transmitting device, and which includes a plurality of heat sinks;
wherein heat dissipating efficiency of a heat sink located at a center of the protective plate is higher than heat dissipating efficiency of a heat sink located at an edge of the protective plate.

2. The device according to claim 1, wherein a heat dissipating area of the heat sink located at the center of the protective plate is greater than a heat dissipating area of the heat sink located at the edge of the protective plate.

3. The device according to claim 2, wherein a length of the heat sink located at the center of the protective plate is greater than a length of the heat sink located at the edge of the protective plate.

4. The device according to claim 2, wherein a height of the heat sink located at the center of the protective plate is greater than a height of the heat sink located at the edge of the protective plate.

5. The device according to claim 1, wherein the chassis base comprises a reinforcement member corresponding to the protective plate, and the protective plate is coupled to the reinforcement member by a screw fixed to the chassis base.

6. The device according to claim 5, further comprising:
a first thermal conductive medium interposed between the driving chips and the reinforcement member; and
a second thermal conductive medium interposed between the driving chips and the protective plate.

7. The device according to claim 6, wherein the first thermal conductive medium and the second thermal conductive medium are made of any one of a solid metal foil, an acrylic material obtained by adding a thermal conductive filler, graphite and silicon.

8. The device according to claim 6, wherein the first thermal conductive medium and the second thermal conductive medium are made of any one of a gelled silicon sheet having a standard thermal conductivity and a rubber sheet.

9. The device according to claim 1, wherein the heat sinks are made of aluminum.

10. The device according to claim 1, wherein the signal transmitting device on which the driving chips are mounted comprises any one of a tape carrier package (TCP) and a chip on film (COF).

11. The device according to claim 1, further comprising a heat dissipating sheet mounted on the rear surface of the plasma display panel.

12. The device according to claim 1, further comprising a thermal conductive medium interposed between the driving chips and the protective plate.

13. The device according to claim 12, wherein the thermal conductive medium is made of any one of a material obtained by adding a thermal conductive filler to one of a solid metal foil, an acrylic material, graphite and silicon.

14. The device according to claim 12, wherein the thermal conductive medium is made of any one of a gelled silicon sheet having a standard thermal conductivity and a rubber sheet.
